(19) United States
(12) Patent Application Publication
(10) Pub. No.: US 2006/0088961 A1
(43) Pub. Date: Apr. 27, 2006

(54) Method of fabricating poly crystalline silicon TFT

(75) Inventors: Ji-sim Jung, Incheon-si (KR); Takashi Noguchi, Seongnam-si (KR); Do-young Kim, Suwon-si (KR); Jang-yeon Kwon, Seongnam-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Suwon-si (KR)

(21) Appl. No.: 11/247,134

(22) Filed: Oct. 12, 2005

(30) Foreign Application Priority Data
Oct. 12, 2004 (KR) 10-2004-0081406

(51) Int. Cl. H01L 21/84; H01L 21/20

(52) U.S. Cl. 438/149; 438/482; 438/486

(57) ABSTRACT

A method of fabricating a poly crystalline silicon thin film transistor (TFT) is provided. The method includes the operations of forming a poly crystalline silicon having a source, a drain, and a channel region between the source and the drain on a substrate in a predetermined pattern; forming an insulating layer on the poly crystalline silicon; forming a silicon-based heat absorption material layer on the insulating layer; exposing the source and the drain by patterning the insulating layer and the heat absorption material layer and forming a gate and a gate insulating layer corresponding to the channel region; injecting impurities into the source, the drain, and the gate; and heat processing the gate insulating layer and the heat absorption material layer by applying thermal energy to the heat absorption material layer. In the heat treatment, the gate material absorbs some of the heat and passes the remaining heat. The heat treatment of the gate insulating layer under the gate can be performed efficiently.

### CROSS-REFERENCE TO RELATED PATENT APPLICATIONS

This application claims the benefit of Korean Patent Application No. 10-2004-0081406, filed on Oct. 12, 2004, in the Korean Intellectual Property Office, the disclosure of which is incorporated herein in its entirety by reference.

### BACKGROUND OF THE DISCLOSURE

1. Field of the Disclosure

The present disclosure relates to a method of fabricating a poly crystalline silicon thin film transistor (TFT).

2. Description of the Related Art

Poly crystalline silicon (poly-Si) has a higher field effect mobility than that of amorphous Si (a-Si), and thus, is utilized in flat panel display devices and various other electronic devices such as solar batteries.

In general, in order to obtain poly-Si crystalline of high quality, a heat resistive material such as a glass substrate is used. A high temperature a-Si deposition method such as chemical vapor deposition (CVD) or plasma enhanced CVD (PECVD) is used to form poly-Si on a glass substrate.

The maximum size of crystalline grains obtained by the conventional method is about 3000-4000 Å, and it is difficult to obtain particles having a size larger than about 3000-4000 Å. Therefore, a technique for fabricating poly-Si having larger particles is needed.

In addition, a method of forming a poly-Si electronic device on a plastic substrate has been investigated. In order to prevent the plastic from warping due to the heat, a lower temperature process such as sputtering should be used for fabricating the poly-Si electronic device. A low temperature process is also required to reduce the thermal shock experienced by the substrate, and to prevent processing defects that are normally generated in a high temperature process when fabricating the device. The plastic substrate has some advantages such as a light weight and flexibility, and thus, has been investigated for its potential application as a substrate of a flat panel display device even though the plastic is susceptible to heat-induced thermal shock.

Carry et. al, (U.S. Pat. No. 5,817,550) suggests a method of preventing plastic from being damaged in a process of forming a silicon channel on a plastic substrate.

In general, when a thin film transistor (TFT) is fabricated, a metal gate electrode is formed, and thereafter, a gate insulating layer is activated by a heat treatment.

The activation of poly-Si is performed by an annealing process using heat or a laser. If the annealing is performed using heat, the temperature of the heat treatment must stay below 200° C., and thus, the activation cannot be performed efficiently. If the annealing is performed using a laser, the laser beam is blocked by the metal gate electrode and cannot be transmitted to the gate insulating layer.

### SUMMARY OF THE DISCLOSURE

The present invention may provide a method of fabricating a poly crystalline silicon thin film transistor (TFT), whereby a gate insulating layer can be activated efficiently at a low temperature.

According to an aspect of the present invention, there may be provided a method of fabricating a thin film transistor including the operations of: forming a poly crystalline silicon having a source, a drain, and a channel region between the source and the drain on a substrate in a predetermined pattern; forming an insulating layer on the poly crystalline silicon; forming a silicon-based heat absorption material layer on the insulating layer; exposing the source and the drain by patterning the insulating layer and the heat absorption material layer and forming a gate and a gate insulating layer corresponding to the channel region; injecting impurities into the source, the drain, and the gate; and heat processing the gate insulating layer and the heat absorption material layer by applying thermal energy to the heat absorption material layer.

The forming of the poly crystalline silicon may include the operations of: depositing amorphous silicon on the substrate; polycrystallizing the amorphous silicon through heat treatment; and patterning the poly crystallized silicon.

The poly crystallization process may be performed in accordance with an excimer laser annealing (ELA) method.

### BRIEF DESCRIPTION OF THE DRAWINGS

The above and other features and advantages of the present invention will become further apparent from exemplary embodiments thereof with reference to the attached drawings in which:

FIG. 1 is a schematic cross-sectional view of a top gate polycrystalline silicon (poly-Si) thin film transistor (TFT) according to the present invention;

FIGS. 2A through 2M are views illustrating processes of fabricating the poly-Si according to the present invention; and

FIGS. 3A and 3B are graphs of the electrical characteristics of a gate insulating layer in the poly-Si TFT according to the present invention.

### DETAILED DESCRIPTION OF THE EXEMPLARY EMBODIMENTS

Hereinafter, embodiments of a method of fabricating a polycrystalline silicon (poly-Si) thin film transistor (TFT) according to the present invention are described with reference to accompanying drawings.

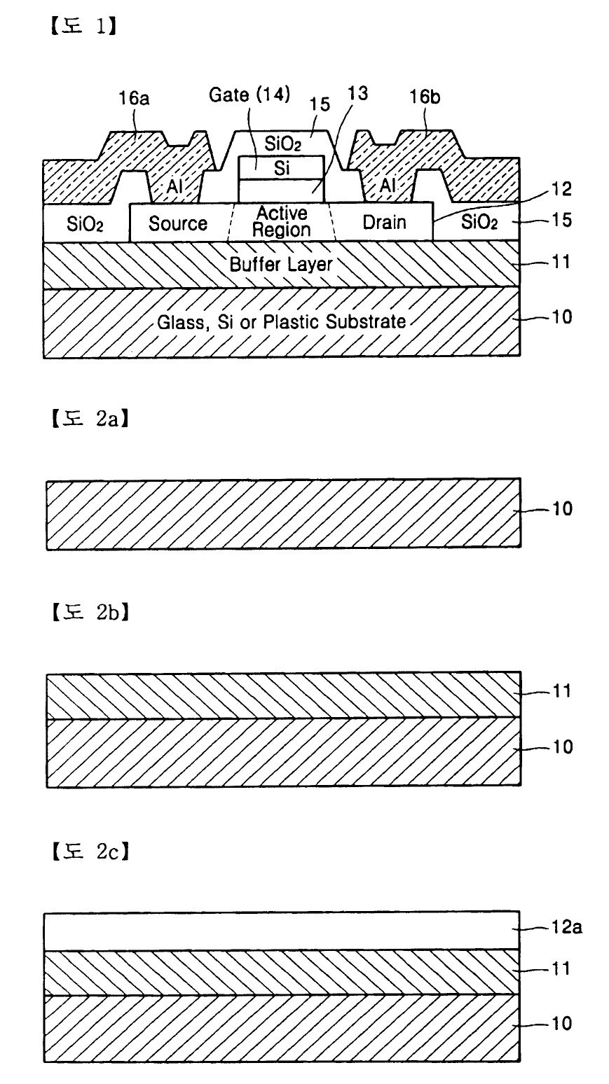

FIG. 1 is a schematic cross-sectional view of a top gate type poly-Si TFT according to the present invention.

Referring to FIG. 1, such a silicon substrate, a glass substrate, or a plastic substrate 10 can be used for supporting the TFT.

On the substrate 10, a buffer layer 11 is formed of an insulating material, for example, SiO₂. In addition, a poly-Si layer 12 with high carrier mobility including an active region as a channel of a predetermined length, through which electrons move, and a source and a drain at the sides of the active region is formed on the buffer layer 11.

A gate insulating layer 13 and a gate layer 14 are formed on the active region of the poly-Si layer 12. The gate 14 is formed of silicon-based material. The gate insulating layer 13 is formed of a material having a high dielectric constant (K), for example, SiO₂, SiNx, or HfO₂, and the gate 14 is formed of doped amorphous silicon (a-Si).

An inter layer dielectric (ILD) 15 is formed on the above stacked layers, and the ILD 15 includes holes 15a and 15b corresponding to the source and drain.

A source electrode 16a and a drain electrode 16b are formed on the holes 15a and 15b of the ILD 15.

In the above structure, the gate insulating layer 13 and the gate 14 are formed of silicon-based material, and are simultaneously patterned. Since the gate 14 is formed of the silicon-based material and helps the activation process to be performed sufficiently by transmitting thermal energy to the gate insulating layer 13 during the activation process, a TFT of high quality can be obtained.

It is desirable that the gate insulating layer 13 and the gate 14 are continuously deposited in the same chamber using the same deposition process, however, they may be formed of different materials from each other.

Hereinafter, the method of fabricating the top gate TFT according to the present invention will be described in further detail.

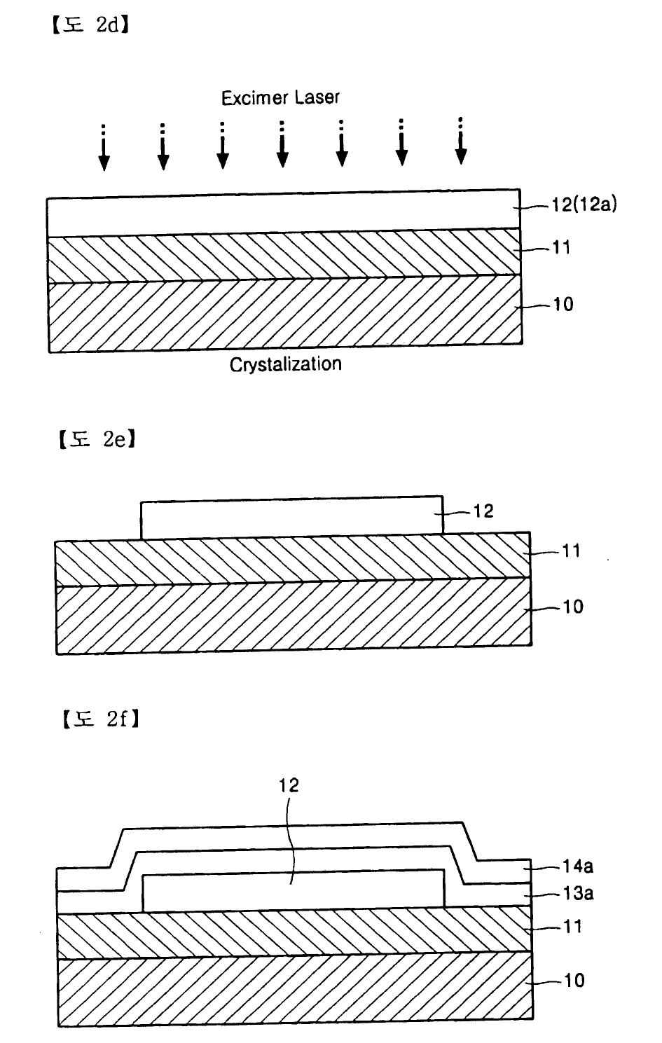

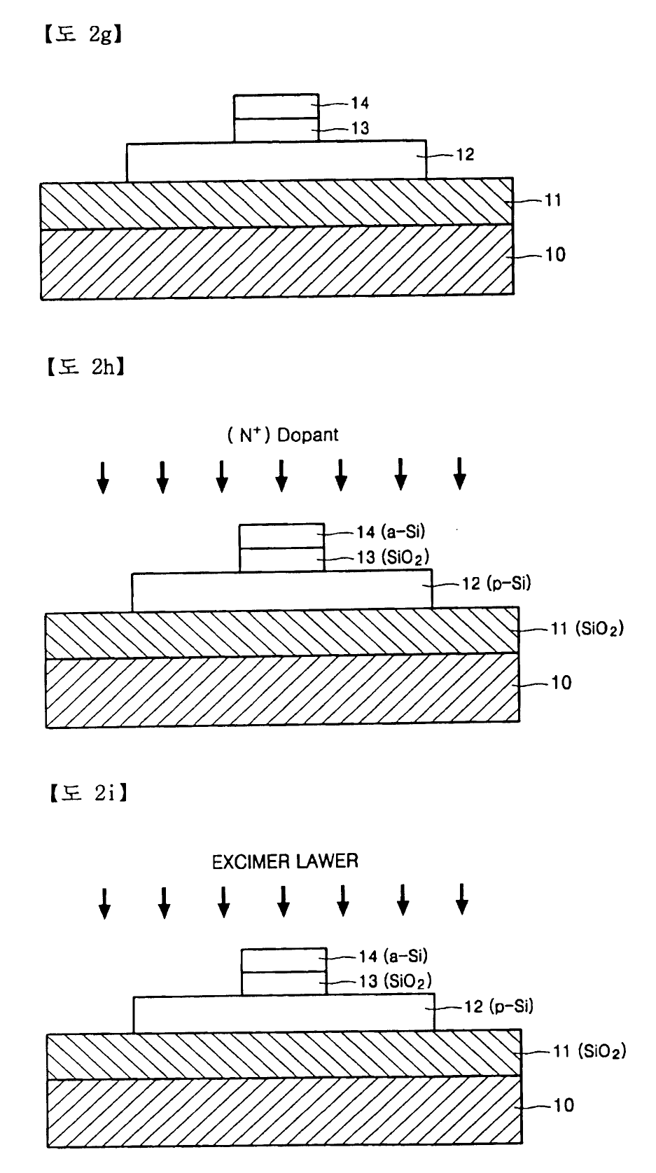

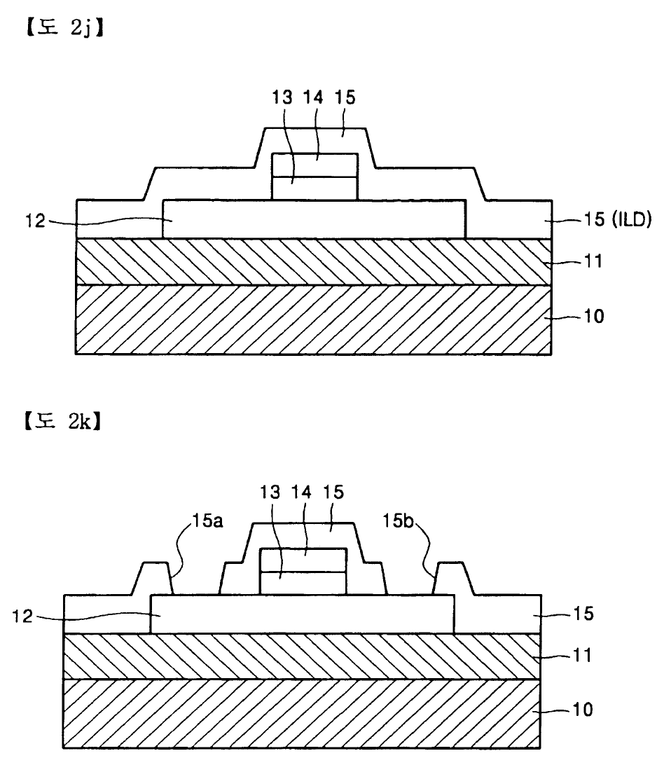

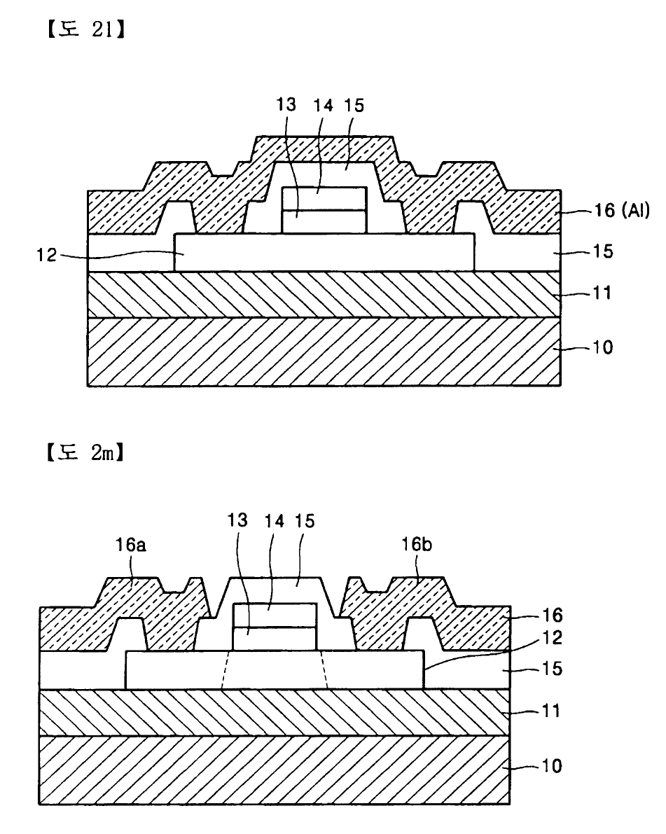

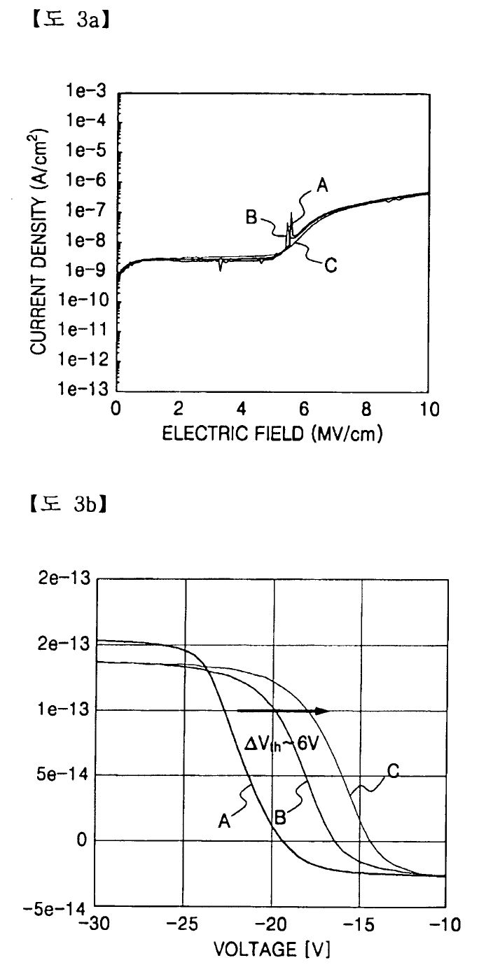

Referring to FIG. 2A, a substrate 10 such as a silicon wafer, a glass substrate, or a plastic substrate is prepared.

Referring to FIG. 2B, the buffer layer 11 is formed on the substrate 10. The buffer layer 11 is formed for electrical insulation and to protect the substrate. If the substrate 10 is a glass or plastic substrate, the buffer layer 11 is formed by additionally depositing SiO₂, and if the substrate 10 is a Si wafer, the buffer layer 11 is formed of naturally formed SiO₂.

Referring to FIG. 2C, an a-Si layer 12a is formed to a thickness of about 500 Å thickness on the buffer layer 11 in the PE-CVD method or a lower pressure CVD method. The a-Si layer 12a is poly-crystallized and patterned, and then, used as the active region, and the source and drain at both sides of the active region.

Referring to FIG. 2D, the a-Si layer 12a is annealed using an excimer laser so as to be crystallized, and a poly-crystalline layer 12 is obtained.

Referring to FIG. 2E, the poly-crystalline layer 12 is patterned in a patterning process to form a so-called “island”. The thus obtained island, that is, the polycrystalline silicon layer 12 has the active region corresponding to the gate 14 that will be fabricated later, and source and drain regions that are not doped yet at both sides of the active region, as shown in FIG. 1.

Referring to FIG. 2F, an SiO₂ gate insulating material layer 13a and an a-Si gate material layer 14a are sequentially deposited in the same chamber on the poly crystalline silicon layer 12. Here, the gate insulating material layer 13a and the gate material layer 14a are continuously obtained by an inductively coupled plasma chemical vapor deposition (ICP-CVD) method with the gate insulating material layer 13a and the gate material layer 14a being formed on the silicon-based material. If the gate insulating material layer 13a and the gate material layer 14a are formed of different materials from each other, the layers are obtained by separate processes.

Referring to FIG. 2G, the gate insulating material layer 13a and the gate material layer 14a are patterned to form the gate 14 and the gate insulating layer 13 under the gate 14. Both ends of the poly crystalline silicon layer 12, that is, the source and drain regions, are exposed through the above patterning process.

Referring to FIG. 2H, an impurity implantation process is performed using a dopant such as boron (B) to grant electrical conductivity to the source and drain regions of the poly crystalline silicon layer 12 and the gate 14.

Referring to FIG. 21, the material layers are heat-treated using a heat source such as an excimer laser. For example, the excimer laser is radiated from the upper portion of the substrate, and the thermal energy passes through the stacked layer and reaches the substrate 10. At that time, the gate 14 absorbs some of the thermal energy, and transmits most of the heat to the gate insulating layer 13 thereunder. The source, drain, and gate are activated by the heat transmission, and an interfacial property of the gate insulating layer is improved.

In addition, referring to FIG. 2J, SiO₂ is deposited on the stacked layers in the CVD method to form an interlayer dielectric (ILD) 15.

Referring to FIG. 2K, a source contact hole 15a and a drain contact hole 15b are formed on the ILD 15 by the general patterning process.

Referring to FIG. 2L, a metal layer 16 such as an Al layer is formed on the stacked layers in a thermal deposition method.

Referring to FIG. 2M, the metal layer 16 is patterned in the general patterning method to form a source electrode 16a and a drain electrode 16b.

According to the method of fabricating the TFT of the present invention, a TFT of high quality can be obtained. According to the present invention, the gate and the gate material under the gate are sequentially deposited in the same chamber, and simultaneously are patterned by a photolithography process.

According to the present invention, the heat is effectively transmitted to the gate after passing through the gate in the activation process, and thus, the heat treatment can be performed efficiently at a low temperature of about 200° C. or lower.

The sequential deposition process of the gate insulating layer and the silicon layer is a feature of the present invention.

When the SiO₂ is deposited for forming the gate insulating layer, it is desirable that SiH₄/O₂/Ar are supplied in a ratio of about 1:25:50 (unit :sccm), the power is controlled to be about 1000 W, and the pressure is about 15 mTorr, and the process is performed at about room temperature.

However, the applicable range of the power is about 600˜1500 W and the applicable range of pressure is about 10˜50 mTorr for forming SiO₂.

The depositions of the gate insulating layer and the a-Si are sequentially performed in an ICP-CVD chamber, and the processing conditions are changed according to the deposited materials. According to the above sequential deposition, the substrate is heated to a low temperature, for instance, about 150° C. without an additional heating source.

In addition, the heat treatment of the a-Si for obtaining the poly crystalline silicon is performed by an excimer laser annealing (ELA) method, and the thermal energy increases from about 100 mJ/cm² to about 210 mJ/cm² in 10 mJ/cm² units.

FIGS. 3A and 3B are graphs of the electrical properties of the gate insulating layer, that is, the SiO₂ thin film in the TFT fabricated by the method according to the present invention. FIG. 3A shows current density according to changes in the electric field before and after the heat treatment. The SiO₂ gate insulating layer formed in the ICP-CVD method according to the present invention is compared with the a-Si gate on the gate insulating layer formed by the laser heat treatment using the heat absorption layer according to the present invention. In FIG. 3A, the curve having the maximum instant peak (A) shows the electrical properties of the gate insulating layer before the heat treatment, the curve having the second highest instant peak (B) shows the electric properties when the gate insulating layer is treated by 250 mJ/cm², and the smooth curve (C) shows the electrical properties when the gate insulating layer is treated by the thermal energy of 400 mJ/cm².

FIG. 3B shows the current density and breakdown voltage properties, and the left curve (A) shows the electrical properties before the heat treatment, the middle curve (B) shows the electrical properties after the heat treatment using the thermal energy of 250 mJ/cm², and the right curve (C) shows the electrical properties after the heat treatment using the thermal energy of 400 mJ/cm². Referring to FIG. 3B, the higher the heat treatment energy, the higher the interfacial characteristics.

According to the present invention, silicon-based material through which thermal energy can pass is used as the gate material, and the activation and annealing of the layers can be performed by a heat treatment without an additional process. Therefore, according to the present invention, the method of fabricating the TFT does not require additional process steps.

The method of fabricating poly Si according to the present invention can be applied to methods for fabricating flat panel display devices, for example, active matrix liquid crystal displays (AMLCD) or active matrix organic light emitting diodes (AMOLED).

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a thin film transistor comprising the operations of:
forming a poly crystalline silicon having a source, a drain, and a channel region between the source and the drain on a substrate in a predetermined pattern;
forming an insulating layer on the poly crystalline silicon;
forming a silicon-based heat absorption material layer on the insulating layer;
exposing the source and the drain by patterning the insulating layer and the heat absorption material layer and forming a gate and a gate insulating layer corresponding to the channel region;
injecting impurities into the source, the drain, and the gate; and
heat processing the gate insulating layer and the heat absorption material layer by applying thermal energy to the heat absorption material layer.

2. The method of claim 1, wherein the forming of the insulating layer on the poly crystalline silicon and the forming of the silicon-based heat absorption material layer on the insulating layer are performed sequentially in the same chamber.

3. The method of claim 2, wherein a gate insulating layer and the heat absorption material layer are continuously formed in an inductively coupled plasma chemical vapor depositon (ICP-CVD) method.

4. The method of claim 1, wherein the forming of the poly crystalline silicon includes the operations of:
depositing amorphous silicon on the substrate;
polycrystallizing the amorphous silicon through heat treatment; and
patterning the poly crystallized silicon.

5. The method of claim 4, wherein the poly crystallization process is performed in an excimer laser annealing (ELA) method.

6. The method of claim 4, wherein the heat treatment of the amorphous silicon layer on the substrate is performed in the ELA method.
